(19) United States
(12) Patent Application Publication
(10) Pub. No.: US 2025/0124965 A1
(43) Pub. Date: Apr. 17, 2025

(54) DRAM MEMORY DEVICE USING A MECHANISM FOR ROW HAMMER MANAGEMENT

(71) Applicant: UPMEM, Grenoble (FR)

(72) Inventor: Fabrice Devaux, Lausanne (CH)

(21) Appl. No.: 18/717,247

(22) PCT Filed: Dec. 7, 2022
(86) PCT No.: PCT/EP2022/084811

§ 371 Date: Nov. 25, 2024

(30) Foreign Application Priority Data
Dec. 9, 2021 (FR) FR2113218

(51) Int. Cl. G11C 11/406

(52) U.S. Cl. CPC G11C 11/40618; G11C 11/40615

(57) ABSTRACT

The invention relates to a memory device that comprises: —a memory bank provided with n memory rows, each row i being liable to effect a row hammer having a range p; —a block for preventing the hammer effect which comprises counting means implementing m hammer counters, each counter k being associated with one or more of the rows i, and is configured to increment a count k by an increment value k_{N}, the increment value k_{N} being a decreasing function of the duration T_{PN} and also a function of the duration T_{AN}, the increment value k_{N} quantifying the effect of the hammer from the one or more rows i on rows j within hammering range; —a row refresh block configured to refresh one or more rows as soon as a count k reaches a threshold value M.

### FIELD OF THE INVENTION

The present invention relates to the field of memories, and in particular to the field of dynamic random access memories.

In particular, the present invention relates to the management of the memory row-hammering effect.

In this respect, the present invention proposes an architecture of a

memory device making it possible to manage and prevent the memory row-hammering effect for large-capacity memory devices without penalizing the performance of said devices.

### TECHNOLOGICAL BACKGROUND OF THE INVENTION

The row-hammering effect in the Dynamic Random Access Memories (“DRAM”) is well known to the person skilled in the art.

This effect has its origin in the repeated activation of a row of a bank of a DRAM. More particularly, when the number of activations of a given row, called the “aggressor row”, exceeds a critical hammering value, the rows which are immediately adjacent to it, called the “victim rows”, see some of their bits inverted.

In order to prevent the row-hammering effect, it may be envisaged, before a row becomes an aggressor, to refresh the two adjacent victim rows according to a preventive refresh procedure.

Such a preventive refresh procedure is, in this respect, described in document FR 3066842. This document in particular discloses a memory device provided with a logic for detecting the triggering of row hammer. This detection logic is configured to monitor and/or count the number of activations of each row of a bank or of a sub-bank of the memory device. The counting data are, in this respect, stored in one or more tables whose number of entries is directly dependent on the size of the memory device (and in particular its capacity).

This memory device known from the prior art is particularly efficient as long as the critical hammering value remains greater than 40,000.

However, the increasing capacity of memory devices requires the consideration of tables comprising a greater number of entries, and which consequently consume much more resources.

Moreover, considering only row hammering at the rows immediately adjacent to the aggressor row, as proposed in document FR 3066842, reaches its limits when the memory device is manufactured according to fine geometries, and in particular at scales smaller than 20 nm.

Indeed, the consideration of finer patterns or geometries inevitably leads to increasing the scope of the row-hammering effect. In particular, an aggressor row of index “i” of a bank or of a sub-bank of memory will not only affect the rows that are immediately adjacent to it (with indices “i-1” and “i+1”), but also, and to a lesser extent, the rows with indices “i-k” and “i+k” (where “k” is an integer strictly greater than 1).

Increasing the scope of the hammering effect thus has two consequences. Firstly, it contributes to increasing the size of tables that can be considered in document FR 3066842. Secondly, it imposes critical hammering values much lower than 40,000, or even lower than 4800.

These two combined effects directly affect the effectiveness of the logic proposed in this document for detecting the triggering of row hammer.

In order to overcome these problems, another algorithm for preventing the row-hammering effect has been proposed in document U.S. Pat. No. 10,885,966. That document also implements tables, and considers a scope of the hammering effect beyond the rows immediately adjacent to an aggressor row. More particularly, the proposed algorithm, in order to limit the resources necessary for its implementation, monitors the activations at the level of sub-banks.

This algorithm, even more efficient than that proposed in document FR 3066842, can be improved for certain memory device architectures.

In particular, this algorithm is generally implemented by means of a Static Random Access Memory (“SRAM”) block.

Generally speaking, the algorithms for preventing the effect of row hammering described in documents FR 3066842 and U.S. Pat. No. 10,885,966, count the row activations without any considerations relating to the dynamics of implementing said activations. Although simple to implement, this strategy ignores the dynamic effect of row hammering, and in particular the time parameters associated with the activation of a given memory row.

One aim of the present invention is therefore to provide a memory device equipped with means for preventing the effect of row hammering, optimized with respect to solutions known in the state of the art.

### BRIEF DESCRIPTION OF THE INVENTION

The aim of the invention is achieved by a DRAM memory device comprising:
at least one DRAM memory bank provided with n memory rows, referred to as row i for i ranging from 1 to n, each row i being liable to effect a row hammer having a range p on one or more rows j, said to be within the hammering range of row i, with j ranging from i+1 to i+p and from i−1 to i−p, each row i being configured to have activation cycles N imposed on it continuously, an activation cycle N comprising an activation A_{N}, of duration T_{AN}, and a preload P_{N}, of duration T_{PN}, preceding the activation A_{N};
a logic block for preventing the hammer effect which comprises counting means implementing m hammer counters, called counters k, k ranging from 1 to m, each k counter being associated with one or more of the rows i, and is configured to increment, after the end of each activation cycle N of one or more of the rows i with which it is associated, a count k by an increment value K_{N}, the increment value kn being a decreasing function of the duration T_{PN} and also a function of the duration T_{AN}, the increment value K_{N} quantifying the hammer effect from the one or more of the rows i on rows j within hammering range;
a row refresh logic block configured to refresh one or more rows as soon as a count k of one of the associated counters k reaches a threshold value M, the threshold value M being chosen to prevent the row hammer effect.

In one embodiment, the increment value k_{N} is an increasing function of the time T_{AN}.

According to one embodiment, the count k is incremented by the increment value k_{N} only after the end of the preload P_{N+1} of the activation cycle N+1 immediately following the activation A_{N} of the activation cycle N, the increment value k_{N} also being a decreasing function of a duration T_{P(N+1)} of the preload P_{N+1}.

According to one embodiment, the set of counters k are saved in at least one table.

According to one embodiment, the logic block for preventing the row hammer effect is configured to measure, for each activation cycle N, the duration T_{AN} of each activation A_{N}, and the duration T_{PN} of each preload P_{N}.

According to one embodiment, the at least one DRAM memory bank forms a memory bank divided into p sub-banks, each sub-bank h, for h ranging from 1 to p, forming contiguous sections of rows of the memory bank, the number m of counters k is equal to the number p of sub-banks h such that each counter k, for k ranging from 1 to p, is associated with a sub-bank h of its own, for h ranging from 1 to p.

According to one embodiment, the logic block for preventing the hammer effect is configured to reset or decrement the counter k associated with a sub-bank h as soon as at least one row of said sub-bank k has been refreshed.

According to one embodiment, the number m of counters k is equal to the number n of memory rows, such that each counter k, for k ranging from 1 to n, is associated with its own row i, for i ranging from 1 to n.

According to one embodiment, the refresh logic block is also configured to reset or decrement the counter k as soon as the row, or one of the rows, associated with this counter has been refreshed.

According to one embodiment, the refresh logic block is also configured to perform periodic refreshes of the memory row set at regular time intervals.

According to one embodiment, the increment value k_{N} is the sum of a first increment value and a second increment value, the first increment value being a function of a delay between activation N−I of the activation cycle N−I and activation N of the activation cycle N, the second increment value characterizing the activation duration T_{AN}, of the activation cycle N,

According to one embodiment, the determination of the first value and second value involves a first table and a second table, respectively.

The invention also relates to a method for preventing the memory row hammer effect of a DRAM device, the DRAM device comprising at least one DRAM memory bank provided with n memory rows called row i for i ranging from 1 to n, the method comprising the implementation of an algorithm for preventing the row hammer effect, said algorithm implementing:
m hammer counters, called counters k, k ranging from 1 to m, each k counter being associated with one or more of the rows i, and is configured to increment, after the end of each activation cycle N of one or more of the rows i with which it is associated, a count k by an increment value k_{N}, the increment value k_{N} being a decreasing function of the duration T_{PN} and also a function of the duration T_{AN}, the increment value K_{N} quantifying the hammer effect from the one or more of the rows i on rows j within hammering range;
a row refresh logic block configured to refresh one or more rows as soon as a count k of one of the associated counters k reaches a threshold value M, the threshold value M being chosen to prevent the row hammer effect.

In one embodiment, the increment value k_{N} is an increasing function of the time T_{AN}.

According to one embodiment, the algorithm implements the following steps:

A. Determining the duration T_{PN};

B. Determining the duration T_{AN}:

C. On the basis of the durations T_{PN} and T_{AN}, determining an increment value k_{N} of a counter k associated with row i;

D. Incrementing the counter k by the increment value K_{N};

E. Refreshing one or more rows i as soon as the count k of the counter k associated with said one or more rows i reaches the threshold value M.

Step E. may advantageously be followed by a step F. of decrementing or resetting the count k of the counter k in question.

### BRIEF DESCRIPTION OF THE DRAWINGS

Other features and advantages of the invention will emerge from the following detailed description of the invention with reference to the appended figures, in which:

FIG. 1 is a schematic representation of a memory device capable of being implemented within the scope of the present invention;

FIG. 2 is a schematic representation of a DRAM memory cell capable of being implemented within the scope of the present invention;

FIG. 3 is a diagrammatic representation of two successive activation cycles N and N+1;

FIG. 4 is a schematic representation of a memory bank divided into sub-banks.

### DETAILED DESCRIPTION OF THE INVENTION

The present invention concerns a Dynamic Random Access Memory (DRAM) device provided with a logic block for preventing row hammer.

In particular, the memory device according to the present invention comprises at least one DRAM memory bank provided with n memory rows, referred to as row i for i ranging from 1 to n. More particularly, each row i is liable to effect a row hammer having a range p on one or more rows j, said to be within the hammering range of row i, with j ranging from i+1 to i+p and from i−1 to i−p. Furthermore, and during operation, each row i is configured to have activation cycles N imposed on it continuously, an activation cycle N comprising an activation A_{N}, of duration T_{AN}, and a preload P_{N}, of duration T_{PN}, preceding the activation A_{N};

The memory device according to the present invention further comprises a logic block for preventing the row hammer effect. Said logic block for preventing the row hammer effect particularly comprises counting means implementing m hammer counters, referred to as counters k, k ranging from 1 to m, each counter k being associated with one or more of the rows i. In this respect, each counter k is configured to increment, at the end (or even after) the end of each activation cycle N of one or more of the rows i with which it is associated, a count k by an increment value K_{N}, the increment value K_{N} being a decreasing function of the duration T_{PN} and is a function of the duration the increment value k_{N} quantifying the hammering effect of one or more of the rows i. In particular, the increment value k_{N} can be an increasing function of the duration T_{AN}.

However, the invention is not limited to this last aspect, and it may be possible to consider an increment value k_{N} which is a decreasing function of the duration T_{AN}.

It is also understood, but not necessary to specify, that not all counters k are necessarily associated with the same number of rows i.

Finally, the memory device comprises a row refresh logic block configured to refresh one or more rows j as soon as the count k of the counter k associated with said one or more rows i reaches a threshold value M, the threshold value M being chosen to prevent the row hammer effect.

Thus, a memory device operating according to the principles of the present invention implements an algorithm (a method) for preventing the effects of row hammer.

In particular, as soon as an activation cycle N of a row i is implemented, the algorithm for preventing row hammer effects comprises: A. Determining the duration T_{PN};

B. Determining the duration T_{AN};

C. On the basis of the durations T_{PN} and T_{AN}, determining an increment value K_{N} of a counter k, the counter k being associated with row i (and potentially other rows);

D. Incrementing the counter k by the increment value K_{N};

E. Refreshing one or more rows i as soon as the count k of the counter k associated with said one or more rows i reaches the threshold value M.

Step E. may advantageously be followed by a step F. of decrementing or resetting the count k of the counter k in question.

Step C. may comprise the implementing of a table, particularly a first table and a second table. In this respect, the first table is configured to enable determination of the contribution PN to the increment value k_{N} associated with the duration T_{PN} duration, while the second table is configured to enable determination of the contribution A_{N} to the increment value k_{N} associated with the duration T_{AN}. It is understood that the sum of the contributions A_{N} and P_{N} is equal to the increment value k_{N}.

By way of example, but without limiting the invention to this aspect, the increment value for an activation cycle N of a row i can be broken down into the sum of two increment values referred to respectively as the first increment value and the second increment value.

In particular, the first cross-talk increment value, for an activation N of row i, can be calculated as a function of a delay between activation N−1 (of activation cycle (N−1)) and activation N (of activation cycle N). This time is the sum of the activation duration T_{A(N-1)}and the preload duration T_{PN}. A first table can be used to provide an increment value k_{N} as a function of this period. The number of entries in the first table can be limited by various techniques well known to those skilled in the art, such as, but not limited to, interpolation and/or the use of non-linear tables.

The second increment value, known as the “injection increment”, characterizes the injection of electrons by a row i, during its activation, into rows adjacent to row i. A second table may be implemented. However, unlike the first table, the second table is only characteristic of the activation duration T_{AN} (and consequently ignores the preload).

Alternatively, or additionally, the increment value k_{N} can follow a mathematical law which varies, for example and in a non-limiting way, linearly as a function of the preload duration and the activation duration on the one hand, and, on the other hand, of the activation duration.

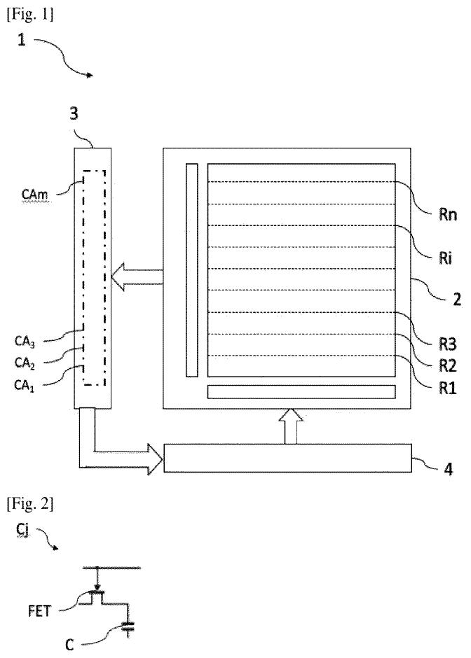

The determination of this mathematical law is within the grasp of the person skilled in the art. That person will be able to determine its shape either by means of experimental measurements or simulations.

[FIG. 1] shows a memory device 1 according to the terms of the present invention. In particular, memory device 1 comprises at least one memory bank 2 provided with n memory rows Rᵢ, referred to as rows i.

In particular, each row i, for i ranging from 1 to n, comprises m memory cells called cells j for integers j ranging from 1 to m.

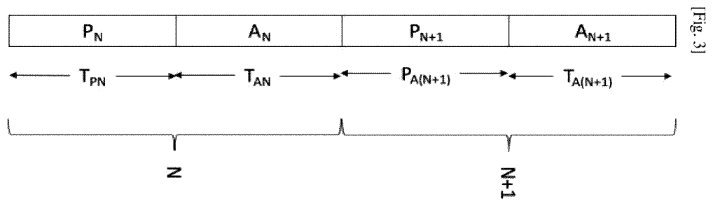

Each cell j Cj, as shown in [FIG. 2], comprises, for example but without limitation, an FET and a capacitor C. In particular, the capacitor C forms a reservoir for storing the information of the memory cell in question.

As shown in [FIG. 3], each row i is configured for continuous N activation cycles. In particular, an N activation cycle comprises an activation A_{N}, of duration T_{AN}, and a preload P_{N}, of duration T_{PN}, preceding the A_{N} activation. It is understood that the durations T_{AN} and T_{PN} are characteristic of a given activation cycle N. In other words, an activation cycle L (with L different from N) will have durations T_{AL} and T_{PL} that are likely to be different from durations T_{AN} and T_{PN}.

In the context of the present invention, a row i is likely to exert a hammer effect of range p (p being greater than or equal to 1). In other words, as soon as a row i is activated, it will hammer on its 2 p nearest-neighbor rows. In particular, the 2 p nearest-neighbor rows comprise a first group of p rows at respective topological distances denoted k, for k ranging from I to p, and a second group of p rows at respective topological distances denoted −k, for k ranging from 1 to p. More particularly, the first and second groups are arranged on either side of row i, respectively.

In this respect, the article by Lois Orosa et al, “A Deeper Look into Row Hammer's Sensitivities: Experimental Analysis of Real DRAM Chips and Implications on Future Attacks and Defenses”, MICRO '21: MICRO-54: 54th Annual 1EEE/ACM International Symposium on Microarchitecture October 2021 Pages 1182-1197 (hereafter “Lois”), presents an experimental study relating to the influence of certain parameters on the row hammer effect. In particular, the authors of this study were able to observe that the hammer effect of a row i on neighboring rows depends on the activation duration of row i, but also on its preload duration.

In particular, according to this study, the weight of the hammer effect by a row, known as the aggressor row, seems to decrease with the preload duration and also varies with the activation duration of said aggressor row. In particular, the weight of the row-hammering effect appears to be an increasing function of activation duration. However, it cannot be ruled out that, under certain conditions, the effect of activation duration on the row hammer effect could be reversed. The authors of the Lois study attempt to provide an explanation for this dependency. They indicate, particularly in section 6.3 of Lois, that the hammering effect comprises two components: Electromagnetic coupling (crosstalk) and electron injection. According to the Lois study, lengthening the preload duration decreases the electromagnetic coupling component and therefore hammering, while lengthening the activation duration would decrease the electromagnetic coupling component but increase the electron injection component. The result of this aspect would be an increase in the hammer effect. Nevertheless, if the respective weights of the two components in the hammer effect were to change, it is possible that an increase in activation duration would reduce the hammering force rather than worsen it, as was the case at the time the “Lois” article was written.

On the basis of these observations, the authors of this study argue, notably on page 12, section 8.2), sub-section “Improvement 5” of the aforementioned article, that monitoring the activation and load times is not feasible without implementing significant storage resources. Alternatively, they offer mechanisms that consist of limiting the activation durations of memory rows when read and/or write operations are required.

The present invention proposes a method of managing the row hammer effect based on the use of counters.

In particular, the memory device 1 comprises a logic block for preventing the row hammer effect 3. The logic block for preventing the row hammer effect 3 comprises, in this respect, counting means implementing m hammer counters CA_{K}, called counters k, k ranging from 1 to m.

More particularly, each counter k is associated with one or more rows i, and is configured to increment, after the end of each activation cycle N of one or more of the rows i with which it is associated, a count k by an increment value K_{N}, the increment value k_{N} being an increasing function (it would however be possible to observe a reverse trend under certain conditions) of the duration, and still decreasing, of the duration T_{PN}, the increment value k_{N} quantifying the hammer effect from the one or more of the rows i on rows j within hammering range.

This modulation of the increment value can be achieved by mathematical operations and/or table look-up. The values of the parameters of the mathematical operations and/or table entries can be determined statically, for example during the design of the memory device, or as a function of characteristics measured at the time of the circuit manufacturing test. Advantageously, in addition, the effect of the temperature or supply voltage of said memory device can also be taken into account. The present invention is not, however, limited to these parameters alone, and it will be up to the skilled person to consider, alternatively or additionally, parameters other than those set out in this paragraph.

According to one variant, the count k is incremented by the increment value k only at (or after) the end of the preload P_{N+1} of the activation cycle N+1 immediately following the activation A_{N} of the activation cycle N, such that the increment value k_{N} is also a decreasing function of a duration T_{P(N+1)} of the preload P_{N+1}.

Also advantageously, the set of counters k can be saved in at least one table.

Finally, the memory device 1 according to the present invention also comprises a row 4 refresh logic block configured to refresh one or more rows as soon as the count k of the counter k associated with said one or more rows i reaches a threshold value M, it being understood that the threshold value M is chosen to prevent the row hammer effect. The determination of this value is left to the discretion of the person skilled in the art, who may use experimental measurements or numerical simulations for this purpose.

It is also understood that the value M also takes into account a count delay effect. This is because, unlike the prior art documents cited in the present invention, counter incrementation only takes place after activation, or even the preload that follows the activation cycle in question. This delay effect can be taken into account when determining the threshold value M.

According to the present invention, and unlike Lois' prediction, taking into account the activation and preload durations T_{PN} does not require the implementation of additional storage means compared with solutions known from the prior art, and in particular those proposed in documents FR 3066842 and U.S. Pat. No. 10,885,966.

Rather, modulating the increment only requires knowledge of a mathematical law obtained experimentally or by simulation.

Furthermore, and in contrast to the solutions proposed in the prior art, the incrementation of a counter k only takes place at the end of the activation cycle N, and possibly at the end of the preload P_{N+1} of the activation cycle N+1.

In this way, and advantageously, the logic block for preventing row hammer 3 can be configured to determine the duration T_{AN} of each activation A_{N}, and the duration T_{PN} of each preload P_{N}.

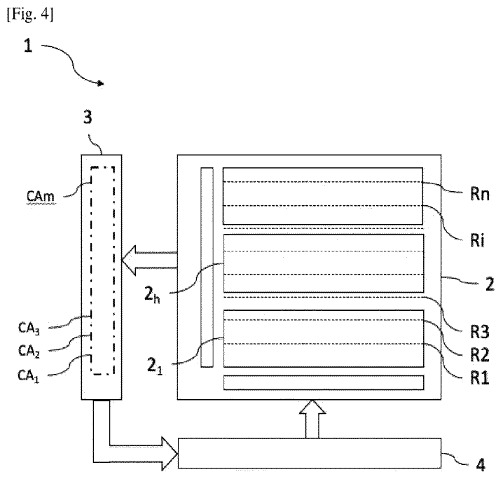

According to an advantageous embodiment, the DRAM memory bank can form a memory bank divided into p sub-banks 2 h, each sub-bank h, for h ranging from 1 to p, forming contiguous sections of rows of the memory bank ([FIG. 4]).

Regardless of the configuration considered, the number m of counters k may be equal to the number n of memory rows, such that each counter k, for k ranging from 1 to n, is associated with its own row i, for i ranging from 1 to n. According to this configuration, the refresh logic block 4 can be configured to reset (or decrement) the counter k of a row i as soon as the rows j within hammering range of said row i have been refreshed.

Alternatively, the number m of counters k is equal to the number p of sub-banks h, such that each counter k, for k ranging from 1 to p, is associated with its own sub-bank h, for h ranging from 1 to p. According to this configuration, the logic block for preventing the hammer effect is configured to reset or decrement the counter k associated with a sub-bank h as soon as a row of said sub-bank k has been refreshed.

Finally, the refresh logic block 4 is also configured to perform periodic refreshes at regular time intervals of the set of memory rows.

Thus, the present invention makes it possible to account for the row hammer effect in memory devices implementing activation counters. However, the counting mode proposed in the present invention proposes to take into account a temporal context that makes it possible to modulate the increment values based on activation and preload durations.

Of course, the invention is not limited to the described embodiments and variant embodiments may be envisaged without departing from the scope of the invention as defined by the claims.

1. A DRAM memory device which comprises:
at least one DRAM memory bank provided with n memory rows, referred to as row i for i ranging from 1 to n, each row i being liable to effect a row hammer having a range p on one or more rows j, said to be within the hammering range of row i, with j ranging from i+1 to i+p and from i−1 to i−p, each row i being configured to have activation cycles N imposed on it continuously, an activation cycle N comprising an activation A_{N}, of duration T_{AN}, and a preload P_{N}, of duration T_{PN}, preceding the activation A_{N};
a logic block for preventing the hammer effect which comprises counting means implementing m hammer counters, called counters k, k ranging from 1 to m, each k counter being associated with one or more of the rows i, and is configured to increment, after the end of each activation cycle N of one or more of the rows i with which it is associated, a count k by an increment value k_{N}, the increment value k being a decreasing function of the duration T_{PN} and also a function of the duration T_{AN}, the increment value k_{N} quantifying the hammer effect from the one or more of the rows i on rows j within hammering range;
a row refresh logic block configured to refresh one or more rows as soon as a count k of one of the associated counters k reaches a threshold value M, the threshold value M being chosen to prevent the row hammer effect.

2. The device according to claim 1, wherein the increment value k_{N} is an increasing function of the time T_{AN},

3. The device according to claim 1, wherein, the count k is incremented by the increment value k_{N} only after the end of the preload P_{N+1} of the activation cycle N+1 immediately following the activation A_{N} of the activation cycle N, the increment value k_{N} also being a decreasing function of a duration T_{P(N+1)} of the preload P_{N+1}.

4. The device according to claim 1, wherein the set of counters k are saved in at least one table.

5. The device according to claim 1, wherein the logic block for preventing the row hammer effect is configured to measure, for each activation cycle N, the duration T_{AN} of each activation A_{N}, and the duration T_{PN} of each preload PN.

6. The device according to claim 1, wherein the at least one DRAM memory bank forms a memory bank divided into p sub-banks, each sub-bank h, for h ranging from 1 to p, forming contiguous sections of rows of the memory bank, the number m of counters k is equal to the number p of sub-banks h such that each counter k, for k ranging from 1 to p, is associated with a sub-bank h of its own, for h ranging from 1 to p.

7. The device according to claim 6, wherein the logic block for preventing the hammer effect is configured to reset or decrement the counter k associated with a sub-bank h as soon as at least one row of said sub-bank k has been refreshed.

8. The device according to claim 1, wherein the number m of counters k is equal to the number n of memory rows, so that each counter k, for k ranging from 1 to n, is associated with a row i, for i ranging from 1 to n, which is its own.

9. The device according to claim 8, wherein the refresh logic block is also configured to reset or decrement the counter k as soon as the row, or one of the rows, associated with this counter has been refreshed.

10. The device according to claim 1, wherein the refresh logic block is also configured to perform periodic refreshes of the memory row set at regular time intervals.

11. The device according to claim 1, wherein he increment value k_{N} is the sum of a first increment value and a second increment value, the first increment value being a function of a delay between activation N−1 of the activation cycle N−1 and activation N of the activation cycle N, the second increment value characterizing the activation duration T_{AN}, of the activation cycle N.

12. The device according to claim 11, wherein the determination of the first value and second value involves a first table and a second table, respectively.

13. A method for preventing the memory row hammer effect of a DRAM device, the DRAM device comprising at least one DRAM memory bank provided with n memory rows called row i for i ranging from 1 to n, the method comprising the implementation of an algorithm for preventing the row hammer effect, said algorithm implementing:
-m hammer counters, called counters k, k ranging from 1 to m, each k counter being associated with one or more of the rows i, and is configured to increment, after the end of each activation cycle N of one or more of the rows i with which it is associated, a count k by an increment value k_{N}, the increment value k_{N} being a decreasing function of the duration T_{PN} and also a function of the duration T_{AN}, the increment value k_{N} quantifying the hammer effect from the one or more of the rows i on rows j within hammering range;
a row refresh logic block configured to refresh one or more rows as soon as a count k of one of the associated counters k reaches a threshold value M, the threshold value M being chosen to prevent the row hammer effect.

14. The method for preventing the row hammer effect according to claim 13, wherein the increment value k_{N} is an increasing function of the duration T_{AN}.

15. The method for preventing the row hammer effect according to claim 14, wherein the algorithm implements the following steps:
A. Determining the duration T_{PN};
B. Determining the duration T_{AN};
C. On the basis of the durations T_{PN} and T_{AN}, determining an increment value k_{N} of a counter k associated with row i;
D. Incrementing the counter k by the increment value k_{N};
E. Refreshing one or more rows i as soon as the count k of the counter k associated with said one or more rows i reaches the threshold value M.
F. A step, following step E., for decrementing or resetting the count k of the counter k in question.
